(19) United States
(12) Patent Application Publication
(10) Pub. No.: US 2006/0065296 A1
(43) Pub. Date: Mar. 30, 2006

(54) Projectors and lighting modules thereof

(75) Inventors: Shu-Mei Chien, Bade City (TW); Ko-Hsien Lee, Fongshan City (TW); Jian-Ming Lee, Linkou Township (TW)

Correspondence Address: BIRCH STEWART KOLASCH & BIRCH, PO BOX 747, FALLS CHURCH, VA, 22040-0747, US

(73) Assignee: BENQ CORPORATION, Taoyuan (TW)

(21) Appl. No.: 11/224,102

(22) Filed: Sep. 13, 2005

(30) Foreign Application Priority Data
Sep. 15, 2004 (TW) 93127844

(51) Int. Cl. H01L 35/00; H01L 37/00

(52) U.S. Cl. 136/206

(57) ABSTRACT

Projectors and lighting modules thereof. A projector comprises a light source, a solar collector and a microprocessor. The microprocessor connects and controls the light source. The solar collector connects the microprocessor and receives light from the light source. The solar collector transmits an alarm signal to the microprocessor when suffering excessive temperature.

### BACKGROUND

The invention relates in general to projectors and in particular to lighting modules of projectors with solar collectors capable of converting light energy into electric energy.

A conventional projector generally comprises a lighting module with a lamp serving as a light source, thereby providing light to project images via an optical engine. The efficiency of light energy utilization, however, is about 70˜80% with 20˜30% light dissipation in a conventional projector.

### SUMMARY

Projectors and lighting modules are provided. An embodiment of a projector comprises a light source, a solar collector and a microprocessor. The microprocessor connects and controls the light source. The solar collector connects the microprocessor and receives light from the light source. The solar collector transmits an alarm signal to the microprocessor when suffering excessive temperature.

An embodiment of a lighting module comprises a lamp box, a light source disposed in the lamp box, and a solar collector. The solar collector is disposed between the light source and the lamp box and connected to an inner surface of the lamp box for receiving light and converting light from the light source into electric energy.

### DESCRIPTION OF THE DRAWINGS

FIG. 1 is an exploded diagram of an embodiment of a lighting module;

FIG. 2 is a perspective diagram of an embodiment of a lighting module;

FIG. 3 is a perspective sectional view of an embodiment of a lighting module;

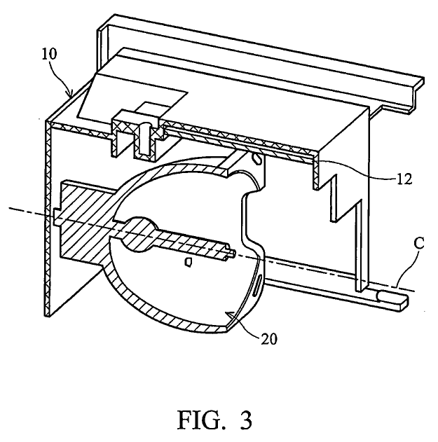

FIG. 4 is a sectional view of the lighting module in FIG. 3; and

FIG. 5 is a block diagram of an embodiment of a projector.

### DETAILED DESCRIPTION

An embodiment of the invention provides a lighting module of a projector with a solar collector. The solar collector can receive light and convert light energy into electric energy.

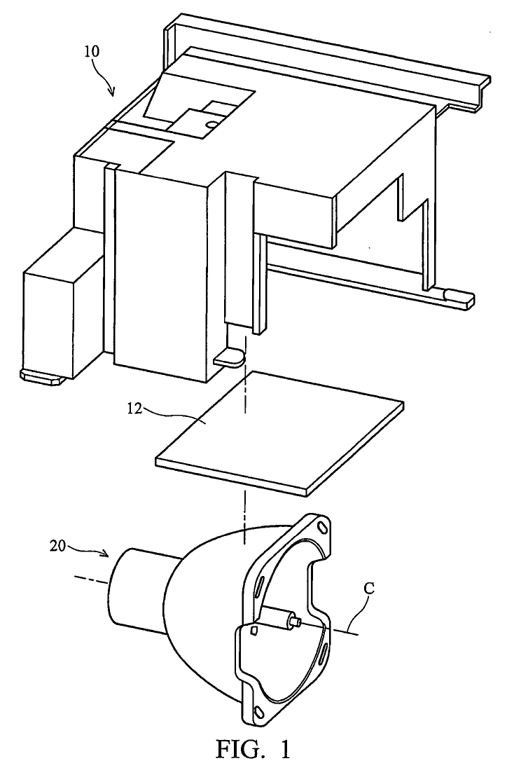

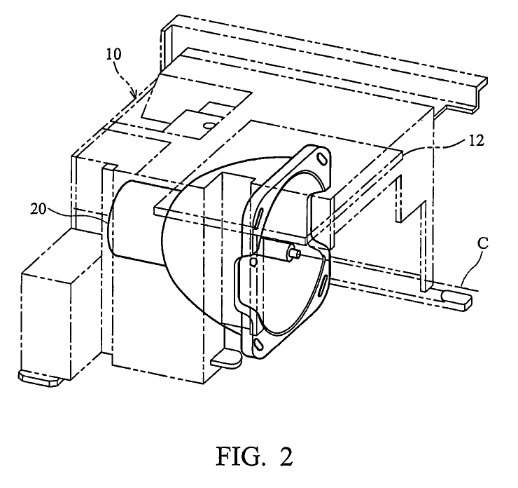

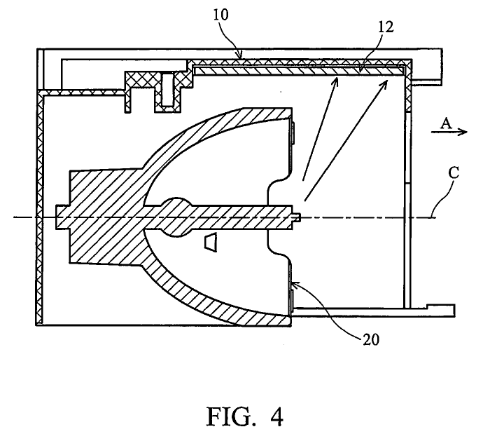

Referring to FIG. 1, a lighting module is disposed in a projector (not shown), comprising a hollow lamp box 10, a light source 20, such as a halogen lamp, and a solar collector 12 disposed therebetween. The solar collector 12, as shown in FIGS. 2˜4, is a flat plate disposed on an inner surface of the lamp box 10 with the light source 20 disposed therein. In FIG. 4, the solar collector 12 is disposed beside the light source 20 and parallel to an central axis C of the light source 20. The solar collector 12 can receive dissipative light diverged from the central axis C, as shown by the arrows in FIG. 4, and further convert light energy into useful electric energy.

Light from the light source 20 progresses primarily in direction A along the central axis C. The solar collector 12 is disposed beyond the light source 20 in direction A, thereby efficiently receiving light dissipated from the light source 20.

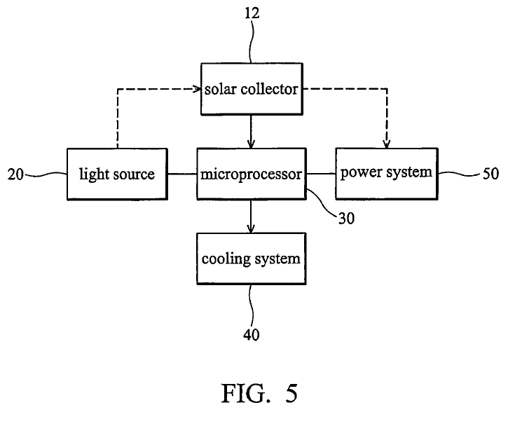

FIG. 5 illustrates a block diagram of an embodiment of a projector with the described lighting module. As shown in FIG. 5, the projector comprises a light source 20, a solar collector 12, a microprocessor 30, a cooling system 40 and a power system 50. The cooling system 40 is used to cool the light source 20. The microprocessor 30 and the light source 20 are electrically connected, enabling microprocessor 30 to control and switch the light source 20. The light source 20 emits light while the projector is on, and light dissipated from the light source 20 can be received and converted into electric energy by the solar collector 12.

Specifically, the solar collector 12 can also be utilized for detection of excessive temperature in the lighting module due to operation of the light source 20. When the solar collector 12 is overheated by the light source 20, an alarm signal is transmitted from the solar collector 12 to the microprocessor 30. Subsequently, the microprocessor 30 activates the cooling system 40 to cool the light source 20. In some embodiments, the microprocessor 30 can increase the speed of a fan in the cooling system 40, thereby cooling the light source 20 to prevent overheating. The microprocessor 30 may also transmit a breaking signal to shut off the light source 20, thereby preventing the light source 20 from failure due to overheating.

As shown in FIG. 5, the microprocessor 30 also electrically connects the power system 50 and the solar collector 12. Dissipative light energy from the light source 20 can be converted into electric energy by the solar collector 12, thus recycling electric power to the power system 50. In some embodiments, the power system 50 may include a rechargeable battery device electrically charged by recycling power from the solar collector 12. Thus, the power system 50 is capable of supplying electrical power for the microprocessor 30 and other systems in the projector without external power supply.

As mentioned, the projector and the lighting module thereof with solar collector can recycle dissipated light energy, thereby potentially saving energy and cost. During operation of the light source, the solar collector converts dissipative light into electric energy and transmits a signal to the microprocessor. When the cooling system does not function normally, the microprocessor 30 may transmit a breaking signal to shut off the light source 20, thereby preventing the light source 20 from failure due to overheating. Thus, the solar collector not only recycles dissipative light energy, but may also potentially prevent the system from overheating, thereby extending life of the lighting module and the projector.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A lighting module, comprising:
a lamp box;
a light source disposed in the lamp box; and
a solar collector disposed between the light source and the lamp box, wherein the solar collector is connected to an inner surface of the lamp box for receiving light and converting light from the light source into electric energy.

2. The lighting module as claimed in claim 1, wherein the solar collector is substantially parallel to a central axis of the light source.

3. The lighting module as claimed in claim 1, wherein the light source comprises a halogen lamp.

4. A projector, comprising:
a light source;
a microprocessor connected to the light source, controlling and switching the light source; and
a solar collector electrically connected to the microprocessor, receiving and converting light from the light source into electric energy, wherein the solar collector transmits an alarm signal to the microprocessor when suffering an excessive temperature.

5. The projector as claimed in claim 4, wherein the microprocessor switches the light source off by receiving the alarm signal.

6. The projector as claimed in claim 4 further comprising a cooling system connected to the microprocessor, wherein the microprocessor activates the cooling system to cool the light source by receiving the alarm signal.

7. The projector as claimed in claim 6, wherein the cooling system comprises a fan, and the microprocessor activates the cooling system and increases the fan speed for cooling the light source when the microprocessor receives the alarm signal.

8. The projector as claimed in claim 4 comprising a power system electrically connecting the solar collector, wherein the solar collector provides electric energy to the power system.

9. The projector as claimed in claim 8, wherein the power system includes a rechargeable battery device charged by the solar collector.

10. The projector as claimed in claim 4 further comprising a lamp box with the light source disposed therein.

11. The projector as claimed in claim 10, wherein the solar collector is connected to an inner surface of the lamp box and located between the light source and the lamp box.

12. The projector as claimed in claim 10, wherein the solar collector is substantially parallel to a central axis of the light source for receiving and converting light from the light source into electric energy.

13. The projector as claimed in claim 10, wherein the light source comprises a halogen lamp.
